(19) United States
(12) Patent Application Publication
(10) Pub. No.: US 2013/0214798 A1
(43) Pub. Date: Aug. 22, 2013

(54) CAPACITANCE MEASUREMENT CIRCUIT AND METHOD FOR MEASURING CAPACITANCE THEREOF

(71) Applicants: Bang-Won Lee, Yongin-si (KR); Byung-Joon Moon, Yongin-si (KR); Jae-Surk Hong, Yongin-si (KR)

(72) Inventors: Bang-Won Lee, Yongin-si (KR); Byung-Joon Moon, Yongin-si (KR); Jae-Surk Hong, Yongin-si (KR)

(73) Assignee: ATLab Inc., Yongin-si (KR)

(21) Appl. No.: 13/824,593

(22) PCT Filed: Oct. 31, 2011
(86) PCT No.: PCT/KR2011/008190

§ 371 Date: Mar. 18, 2013

(30) Foreign Application Priority Data
Nov. 4, 2010 (KR) 10-2010-0109265

(51) Int. Cl. G01R 27/26

(52) U.S. Cl. CPC G01R 27/2605
USPC 324/676

(57) ABSTRACT

Provided are a capacitance measurement circuit and method. In the capacitance measurement circuit and method, a control unit generates a control code a predetermined number of times according to designated rules regardless of the level of a sensing signal, and the control code is changed to measure a capacitance value when the level of the sensing signal corresponding to the generated control code is determined to be normal. Consequently, the measured capacitance value is hardly affected by noise and can be stably output.

### TECHNICAL FIELD

The present invention relates to a capacitance measurement circuit and method, and more particularly, to a capacitance measurement circuit and method capable of reducing influence of noise.

### BACKGROUND ART

As a circuit for measuring a capacitance, a capacitance measurement circuit is generally used to measure the capacitances of various circuits or devices. However, as various portable devices have recently come to provide user interfaces such as a touchpad, a touch screen and a proximity sensor, the application range of a capacitance measurement circuit capable of sensing contact and approach of a user is being extended.

FIG. 1 is a block diagram of an example of a conventional capacitance measurement circuit, which is disclosed in Korean Patent Publication No. 10-2009-0026791. A capacitance measurement circuit 1 shown in FIG. 1 includes a pulse signal generation unit 10, a pulse signal transfer unit 20, a pulse signal detection unit 30, and a control unit 40.

The pulse signal generation unit 10 sets a pulse width of a pulse signal pul according to a control code Ccode transferred from the control unit 40, and generates the pulse signal pul having the set pulse width.

The pulse signal generation unit 10 includes a clock signal generator 11, a variable delay chain VDC, an inverter INV, and an AND-gate AND. The clock signal generator 11 generates and transfers a clock signal clk to the variable delay chain VDC and one terminal of the AND-gate AND. The variable delay chain VDC variably delays the clock signal clk in response to the control code Ccode output from the control unit 40, thereby outputting a delay clock signal dclk. The inverter INV inverts the delay clock signal dclk output from the variable delay chain VDC. And the inverted delay clock signal /dclk is transferred to the other terminal of the AND-gate AND. The AND-gate AND logically multiplies the clock signal clk transferred from the clock signal generator 11 and an inverted delay clock signal /dclk transferred through the variable delay chain VDC and the inverter INV, thereby generating the pulse signal pul having a pulse width corresponding to a delay time of the variable delay chain VDC. The delay time of the variable delay chain VDC corresponds to the control code Ccode. Consequently, the pulse width of the pulse signal pul also corresponds to the control code Ccode.

When a touch object having a predetermined capacitance comes in contact with a pad PAD in the pulse signal transfer unit 20 including a resistor R1 and the pad PAD, a signal level of the pulse signal pul is lowered by the capacitance of the touch object applied through the pad PAD and the resistor R1. Here, a delay pulse signal dpul denotes the pulse pul passed through the resistor R1 and the pad PAD.

At this time, any object having a predetermined capacitance can be applied as the touch object, and a human body in which a large amount of electric charge can be accumulated is a typical example of the touch object.

The pulse signal detection unit 30 senses the delay pulse signal dpul and outputs a sensing signal det. When the signal level of the delay pulse signal dpul is reduced to a predetermined level or less by the capacitance of the touch object, the delay pulse signal dpul is not detected by the pulse signal detection unit 30. Otherwise, even when the control code Ccode input from the control unit 40 is a predetermined value or less and the width of the pulse signal pul is a predetermined value or less, the delay pulse signal dpul is not detected by the pulse signal detection unit 30. The pulse signal detection unit 30 includes a T-flip-flop (TFF) 31 and a period determiner 32. The TFF 31 receives the delay pulse signal dpul in response to the clock signal clk, and is synchronized with a rising edge or falling edge of the clock signal clk to toggle an output signal when the delay pulse signal dpul is received. On the other hand, when the delay pulse signal dpul is not received, the TFF 31 does not toggle the output signal. The period determiner 32 determines whether the output signal of the TFF 31 periodically varies. The period determiner 32 outputs the sensing signal det of a high level when the output signal of the TFF 31 periodically varies, and the sensing signal det of a low level when the output signal of the TFF 31 does not periodically vary.

The control unit 40 includes a code generator 41 and outputs the control code Ccode corresponding to the capacitance of the touch object according to the sensing signal det. When the sensing signal det is applied at a low level, the control unit 40 increases and outputs the control code Ccode. On the other hand, when the sensing signal det is applied at a high level, the control unit 40 reduces and outputs the control code Ccode. In response to the control code Ccode, the variable delay chain VDC of the pulse signal generation unit 10 adjusts a delay time of the clock signal clk and outputs the delay clock signal dclk. Consequently, the width of the pulse signal pul output from the pulse signal generation unit 10 is adjusted by the control code Ccode.

FIGS. 2 and 3 illustrate operation of the capacitance measurement circuit of FIG. 1. Referring to FIGS. 2 and 3, the control unit 40 of the capacitance measurement circuit 1 adjusts the control code Ccode in response to the sensing signal det. In other words, the code generator 41 of the control unit 40 increases the control code Ccode when the sensing signal det output from the pulse signal detection unit 30 is at a low level, and reduces the control code Ccode when the sensing signal det output from the pulse signal detection unit 30 is at a high level.

In response to the control code Ccode, the variable delay chain VDC variably delays the clock signal clk and outputs the delay clock signal dclk, and the pulse signal generation unit 10 changes the width of the pulse signal pul according to a time for which the variable delay chain VDC delays the clock signal clk and outputs the pulse signal pul. The pulse signal detection unit 30 senses the delay pulse signal dpul that is delayed by a capacitance applied through the pad PAD of the pulse signal transfer unit 20, thereby outputting the sensing signal det.

In other words, it is determined whether or not the pulse signal pul can be transferred as the delay pulse signal dpul according to the capacitance applied through the pad PAD. To be specific, when the pulse width of the pulse signal pul is small compared to the capacitance applied through the pad PAD, the pulse signal pul cannot be transferred as the delay pulse signal dpul (i.e., the pulse signal detection unit 30 cannot detect the delay pulse signal dpul), and when the pulse width of the pulse signal pul is large compared to the capacitance applied through the pad PAD, the pulse signal pul can be transferred as the delay pulse signal dpul (i.e., the pulse signal detection unit 30 can detect the delay pulse signal dpul). Thus, the pulse signal detection unit 30 outputs the sensing signal det according to whether or not the delay pulse signal dpul is transferred (i.e., whether or not the delay pulse signal dpul is detected), and the control unit 40 changes the control code Ccode according to the sensing signal det and simultaneously checks the sensing signal det, so that the capacitance applied through the pad PAD can be measured.

In the capacitance measurement circuit 1 of FIG. 1, the code generator 41 increases/reduces the control code Ccode by one bit, and thus the control code Ccode is not changed much by noise. However, even when the control code Ccode is increased/reduced by one bit in actual operation of the capacitance measurement circuit 1 of FIG. 1, the control code Ccode is continuously changed by noise. Such a change in the control code Ccode makes it difficult for the capacitance measurement circuit 1 to stably output the control code Ccode.

### DISCLOSURE

### Technical Problem

The present invention is directed to providing a capacitance measurement circuit capable of reducing influence of noise.

The present invention is also directed to providing a capacitance measurement method for achieving the above purpose.

### Technical Solution

One aspect of the present invention provides a capacitance measurement circuit including: a pulse signal generation unit configured to generate a pulse signal by changing a pulse width of a clock signal in response to a control code; a pulse signal transfer unit having a pad, and configured to output a delay pulse signal by delaying the pulse signal in response to a capacitance applied through the pad; a pulse signal detection unit configured to output a sensing signal by detecting the delay pulse signal in response to the clock signal; and a control unit configured to generate the control code a plurality of times according to designated rules, apply the generated control codes to the pulse signal generation unit, and determine whether or not to change the control code by making a determination on the plurality of sensing signals applied in response to the generated control codes.

The control unit may generate the control code having the same value n times (n is a natural number), apply the generated control codes to the pulse signal generation unit, store values of the sensing signals corresponding to the respective control codes generated n times, and reducing and outputting the control code when a number of 1 is p or more (p is a natural number equal to or smaller than n) at the stored values of the plurality of sensing signals.

The control unit may increase and output the control code when a number of 0 is q or more (q is a natural number equal to or smaller than n) at the stored values of the plurality of sensing signals.

The control unit may output the control code as a capacitance value when an increase and reduction in the control code are repeated a predetermined number of times or more.

The control unit may generate r (r is a natural number) sequentially increasing control codes, apply the r control codes to the pulse signal generation unit, sequentially store values of the sensing signals corresponding to the respective r control codes, and determine that noise is included to output the r sequentially increasing control codes again when, among the plurality of stored sensing signals, a sensing signal having a value of 0 follows a sensing signal having a value of 1.

The control unit may output a control code corresponding to a sensing signal having a value of 1 for the first time as a capacitance value when, among the plurality of stored sensing signals, all sensing signals stored after a sensing signal having a value of 0 have a value of 1.

The control unit may generate s (s is a natural number) sequentially decreasing control codes, apply the s control codes to the pulse signal generation unit, sequentially store values of sensing signals corresponding to the respective s control codes, and determine that noise is included to output the s sequentially decreasing control codes again when, among the plurality of stored sensing signals, a sensing signal having a value of 1 follows a sensing signal having a value of 0.

The control unit may output a control code corresponding to a sensing signal having a value of 0 for the first time as a capacitance value when, among the plurality of stored sensing signals, all sensing signals stored after a sensing signal having a value of 1 have a value of 0.

The control unit may alternately generate control codes corresponding to the maximum and minimum of a first range set within the largest value that the control code can have a plurality of times, apply the generated control codes to the pulse signal generation unit, sequentially store values of the sensing signals corresponding to the respective generated control codes, and determine that noise is included to alternately output the control codes corresponding to the maximum and minimum of the first range a plurality of times again when, among the plurality of stored sensing signals, the sensing signal has a value of 1 with respect to the control code corresponding to the minimum and the sensing signal has a value of 0 with respect to the control code corresponding to the maximum.

The pulse signal detection unit may include: a plurality of amplifiers configured to amplify the delay pulse signal with different gains respectively and output the amplification signals respectively; and a plurality of flip-flops corresponding to the respective amplifiers, and configured to latch the amplification signals and output the latch signals respectively.

The control unit may determine whether or not noise is included by sensing a change in the plurality of latch signals.

Another aspect of the present invention provides a capacitance measurement method including: generating a pulse signal by changing a pulse width of a clock signal in response to a control code; outputting a delay pulse signal by delaying the pulse signal in response to a capacitance applied through a pad; outputting a sensing signal by detecting the delay pulse signal in response to the clock signal; and generating the control code a plurality of times, applying the generated control codes to a pulse signal generation unit, and determining whether or not to change the control code by making a determination on the plurality of sensing signals applied in response to the generated control codes.

Determining whether or not to change the control code may include: generating the control code having the same value n (n is a natural number) times and applying the generated control codes to the pulse signal generation unit; storing values of the sensing signals corresponding to the respective n control codes; and reducing and outputting the control code when a number of 1 is p (p is a natural number equal to or smaller than n) or more at the plurality of stored sensing signals. In this case, determining whether or not to change the control code may further include increasing and outputting the control code when a number of 0 is q (q is a natural number equal to or smaller than n) or more at the plurality of stored sensing signals.

Determining whether or not to change the control code may include:

generating r (r is a natural number) sequentially increasing control codes and applying the r control codes to the pulse signal generation unit; sequentially storing values of sensing signals corresponding to the respective r control codes; and determining that noise is included and outputting the r sequentially increasing control codes again when, among the plurality of stored sensing signals, a sensing signal having a value of 0 follows a sensing signal having a value of 1.

Determining whether or not to change the control code may include: generating s (s is a natural number) sequentially decreasing control codes and applying the s control codes to the pulse signal generation unit; sequentially storing values of sensing signals corresponding to the respective s control codes; and determining that noise is included to output the s sequentially decreasing control codes again when, among the plurality of stored sensing signals, a sensing signal having a value of 1 follows a sensing signal having a value of 0.

Determining whether or not to change the control code may include: alternately generating control codes corresponding to the maximum and minimum of a first range set within the largest value that the control code can have a plurality of times and applying the generated control codes to the pulse signal generation unit; sequentially storing values of the sensing signals corresponding to the respective generated control codes; and determining that noise is included to alternately output the control codes corresponding to the maximum and minimum of the first range a plurality of times again when, among the plurality of stored sensing signals, the sensing signal has a value of 1 with respect to the control code corresponding to the minimum and the sensing signal has a value of 0 with respect to the control code corresponding to the maximum.

### Advantageous Effects

Therefore, in a capacitance measurement circuit and method according to exemplary embodiments of the present invention, a control unit generates a control code a plurality of times according to designated rules regardless of the level of a sensing signal, and the control code is changed to measure a capacitance value when the level of the sensing signal corresponding to the generated control code is determined to be normal. Consequently, the measured capacitance value is hardly affected by noise and can be stably output.

### DESCRIPTION OF DRAWINGS

FIG. 1 is a block diagram of an example of a conventional capacitance measurement circuit.

FIGS. 2 and 3 illustrate operation of the capacitance measurement circuit of FIG. 1.

FIG. 4 is a block diagram of a capacitance measurement circuit according to an exemplary embodiment of the present invention.

FIGS. 5 and 6 illustrate operation of the capacitance measurement circuit of FIG. 4.

FIG. 7 is a flowchart illustrating a capacitance measurement method of the capacitance measurement circuit of FIG. 4.

FIG. 8 is a flowchart illustrating an exemplary embodiment of the capacitance measurement method illustrated in FIG. 7.

FIG. 9 is a flowchart allowing the capacitance measurement circuit of FIG. 4 to output a noise flag signal.

FIG. 10 is a flowchart illustrating another example of a capacitance measurement method of the capacitance measurement circuit of FIG. 4.

FIG. 11 is a flowchart illustrating still another example of a capacitance measurement method of the capacitance measurement circuit of FIG. 4.

FIG. 12 illustrates a concept of another example of a capacitance measurement method of a capacitance measurement circuit according to an exemplary embodiment of the present invention.

FIG. 13 is a block diagram of a capacitance measurement circuit according to another exemplary embodiment of the present invention.

FIG. 14 is a diagram illustrating a process for a pulse signal detection unit of FIG. 13 to detect a delay pulse signal.

FIG. 15 is a flowchart illustrating a capacitance measurement method of the capacitance measurement circuit of FIG. 13.

### MODES OF THE INVENTION

Hereinafter, exemplary embodiments of the present invention will be described in detail. However, the present invention is not limited to the exemplary embodiments disclosed below, but can be implemented in various forms. The following exemplary embodiments are described in order to enable those of ordinary skill in the art to embody and practice the invention.

A capacitance measurement circuit and a method of measuring a capacitance that can reduce influence of noise will be described with reference to the appended drawings.

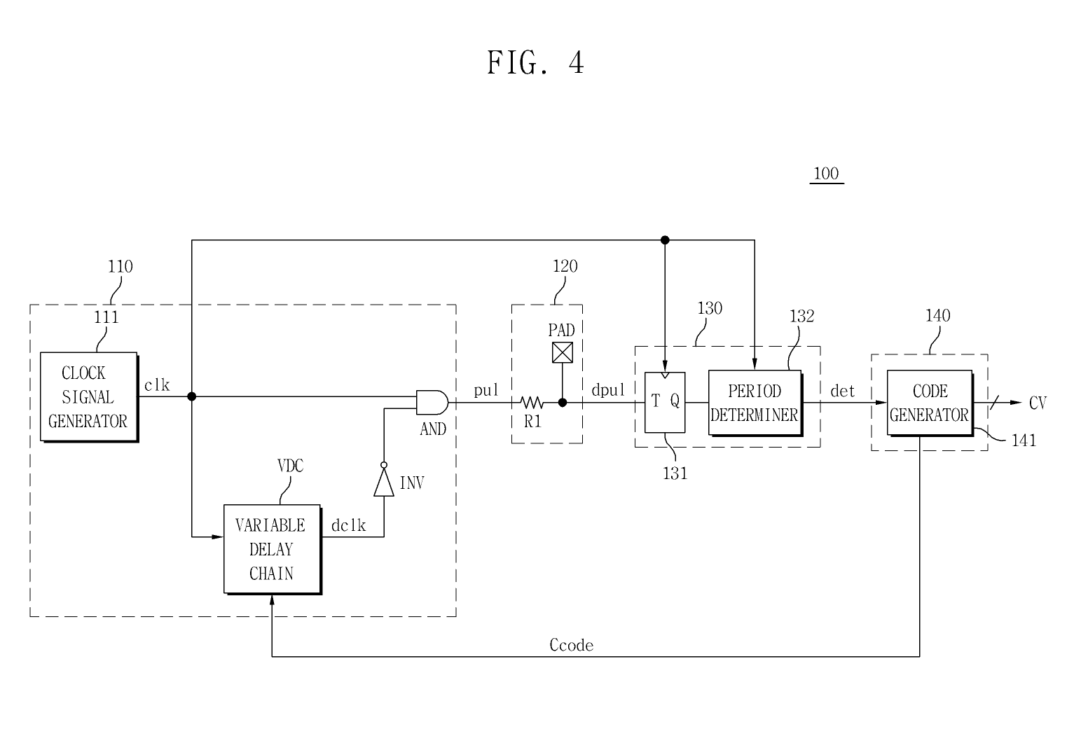

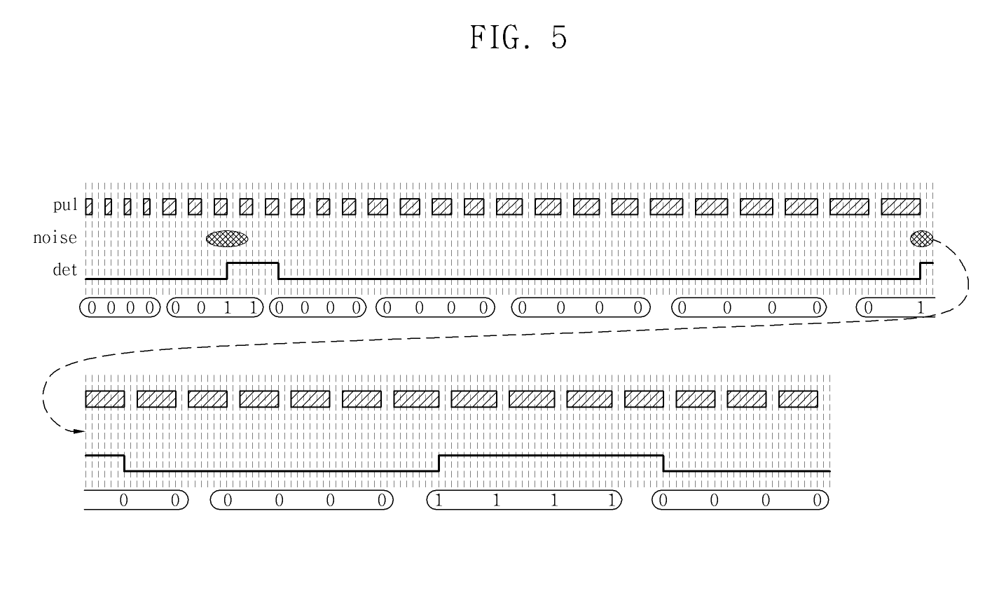

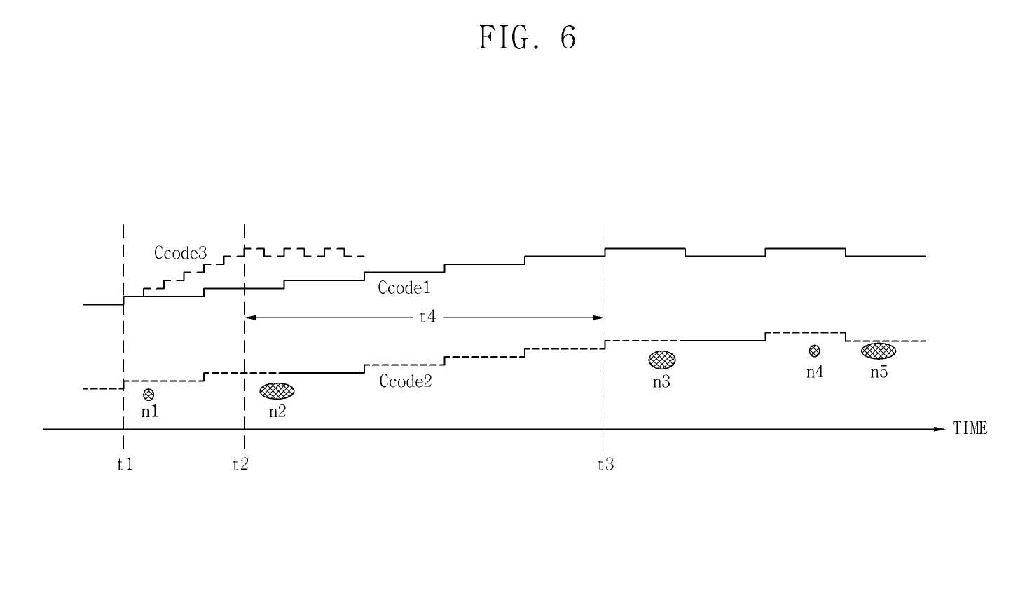

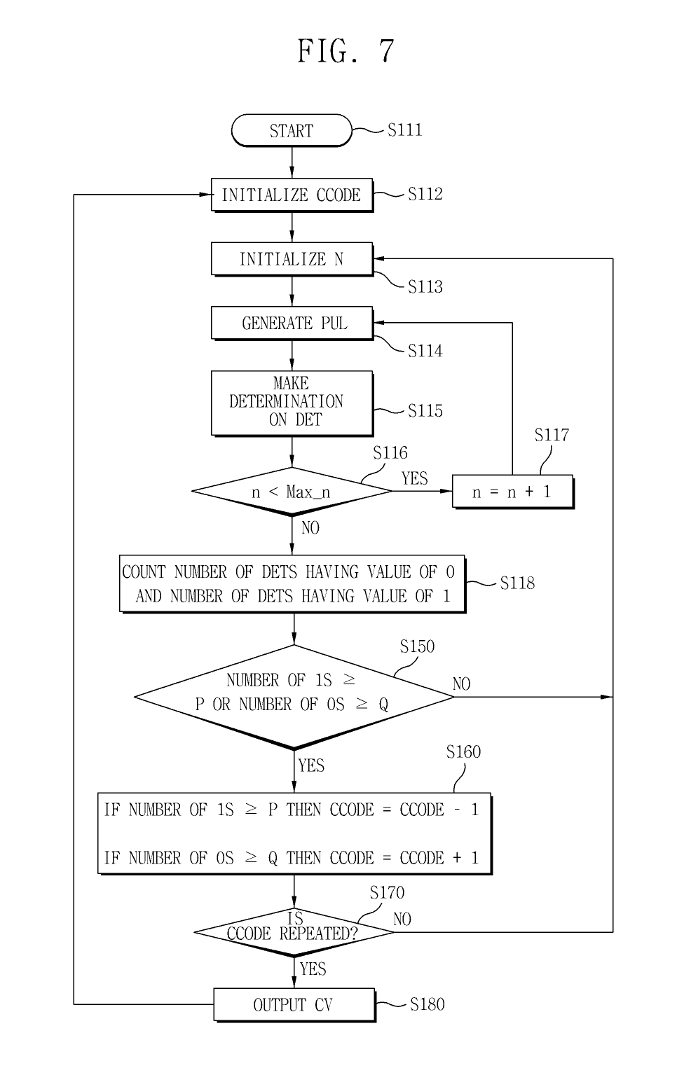

FIG. 4 is a block diagram of a capacitance measurement circuit according to an exemplary embodiment of the present invention, and FIGS. 5 and 6 illustrate operation of the capacitance measurement circuit of FIG. 4.

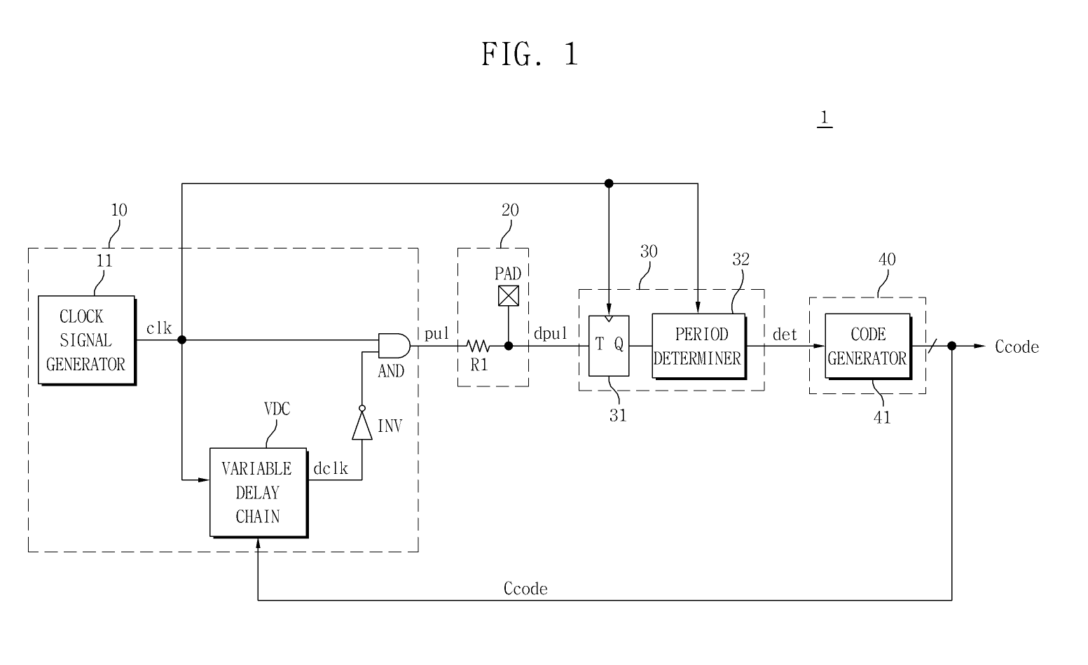

Like in FIG. 1, a capacitance measurement circuit 100 of FIG. 4 includes a pulse signal generation unit 110, a pulse signal transfer unit 120, a pulse signal detection unit 130, and a control unit 140. In the capacitance measurement circuit 100 according to an exemplary embodiment of the present invention, the pulse signal generation unit 110, the pulse signal transfer unit 120, and the pulse signal detection unit 130 operate in the same way as the pulse signal generation unit 10, the pulse signal transfer unit 20, and the pulse signal detection unit 30 of the capacitance measurement circuit 1 of FIG. 1, and will not be described again. However, as illustrated in FIGS. 5 and 6, the control unit 140 of the capacitance measurement circuit 100 according to an exemplary embodiment of the present invention does not immediately change a control code Ccode, unlike the control unit 40 of FIG. 1, even if a sensing signal det of a high or low level is applied. In the capacitance measurement circuit 100 according to an exemplary embodiment of the present invention, the control unit 140 is configured to output the same control code Ccode a plurality of times even if the sensing signal det of a high or low level is applied. To this end, a code generator 141 of the control unit 140 may additionally include a counter.

In FIG. 4, the pulse signal generation unit 110 includes a clock signal generator 111, a variable delay chain VDC, an inverter INV, and an AND-gate AND to output a pulse signal pul having a pulse width corresponding to the control code Ccode. However, the pulse signal generation unit 110 outputting the pulse signal pul having a pulse width corresponding to the control code Ccode in response to the control code Ccode may have various constitutions. In other words, a logic circuit for generating the pulse signal pul may have various constitutions.

In FIG. 4, the pulse signal detection unit 130 includes a T-flip-flop (TFF) 131 and a period determiner 132 to output the sensing signal det according to whether or not a delay pulse signal dpul is received (i.e., whether or not the delay pulse signal dpul is detected). However, the pulse signal detection unit 130 may include another flip-flop and/or other logic circuits.

In FIG. 4, for convenience, the capacitance measurement circuit 100 includes the pulse signal generation unit 110, the pulse signal transfer unit 120, and the pulse signal detection unit 130 to delay a specific signal according to the control code Ccode and output the sensing signal det indicating whether or not the control code Ccode has a value corresponding to the capacitance of a touch object in contact with a pad PAD using the delay time. However, the circuits may be replaced with other logic circuits to perform the same operation. For example, the circuits that sense the capacitance of a touch object applied through the pad PAD according to the control code Ccode and output the sensing signal det (i.e., the pulse signal generation unit 110, the pulse signal transfer unit 120, and the pulse signal detection unit 130) in the exemplary embodiment shown in FIG. 4 may be replaced with other circuits disclosed in Korean Patent Publication No. 10-2007-0005472 or 10-2009-0026791.

FIG. 5 shows a change in the pulse signal pul whose width varies in response to the control code Ccode and the sensing signal det. As shown in FIG. 5, the control unit 140 generates the same control code Ccode a plurality of times, and thus the pulse signal generation unit 110 outputs the pulse signal having the same width the plurality of times. An exemplary embodiment of the present invention in which the number of times that the same control code Ccode is generated is set to, for example, four will be described.

Referring to FIG. 5, the control unit 140 outputs the same control code Ccode four times regardless of the level of the sensing signal det. The pulse signal generation unit 110 outputs the pulse signal pul having the same width four times in response to the control codes Ccode applied with the same value. When capacitance is applied through the pad PAD, the pulse signal transfer unit 120 delays the pulse signal pul and transfers the delay pulse signal dpul to the pulse signal detection unit 130, and the pulse signal detection unit 130 senses the delay pulse signal dpul in response to a clock signal clk and outputs the sensing signal det. The control unit 140 receives the sensing signal det, and checks whether all the sensing signals det are applied at the same level with respect to the pulse signals pul generated with the same width by the same control codes Ccode. In FIG. 5, for convenience, the sensing signal det of a low level (logic-low) is indicated by 0, and the sensing signal det of a high level (logic-high) is indicated by 1.

Here, the value 1 of the sensing signal det means the delay pulse signal dpul is detected at the pulse signal detection unit 130, and the value 0 of the sensing signal det means the delay pulse signal dpul is not detected at the pulse signal detection unit 130.

Also, the sensing signals det corresponding to the pulse signals pul having the same width are expressed as a group.

It can be seen that, when all the sensing signals det are applied at 0 with respect to the pulse signals pul generated with the same width, a capacitance applied through the pad PAD is greater than a capacitance indicated by the control code Ccode, and also noise has not been introduced. Thus, the control unit 140 increases the control code Ccode by one bit and outputs the increased control code Ccode four times. As illustrated in FIG. 5, when the width of the pulse signal pul is increased to two and noise is introduced, the sensing signal det varies. If the same capacitance is being applied through the pad PAD, the sensing signals det need to have the same level with respect to the pulse signals pul having the same width. Thus, when the levels of the sensing signals det vary with respect to the pulse signals pul having the same width, it may be determined that noise has been introduced. Then, the control unit 140 does not change and outputs the control code Ccode four times again. In other words, the pulse signal pul having the same width as before is output four times. On the other hand, when the sensing signals det are output at the same level with respect to the pulse signals pul, it is a normal state in which noise has not been introduced. When all the sensing signals det are applied at 0, the control unit 140 increases the control code Ccode by one bit and outputs the increased control code Ccode four times again.

In other words, after outputting the same control code Ccode four times, the control unit 140 determines that it is the normal state of no noise and changes the control code Ccode if all the sensing signals det corresponding to the control codes Ccode are applied at the same level. On the other hand, if all the sensing signals det corresponding to the control codes Ccode are not applied at the same level, the control unit 140 determines that it is an abnormal state in which noise is introduced and checks whether it is the normal state by applying the same control code Ccode four times.

FIG. 5 illustrates a case in which noise is introduced when the width of the pulse signal pul is 2 and 6. Thus, the control unit 140 outputs a set of the same four control codes Ccode causing the width of the pulse signal pul to be two and a set of the same four control codes Ccode causing the width of the pulse signal pul to be six two times. Thereafter, when the width of the pulse signal pul is seven, all the sensing signals det are applied at the same level of 1. The sensing signals det applied at the same level of 1 denote that the control code Ccode indicates the value of a currently-applied capacitance. Thus, the control unit 140 reduces the control code Ccode by one bit and outputs the reduced control code Ccode four times. Thereafter, when the pulse signal pul repeatedly has a width of six and seven, the control unit 140 outputs the control code Ccode to the outside as a capacitance value CV.

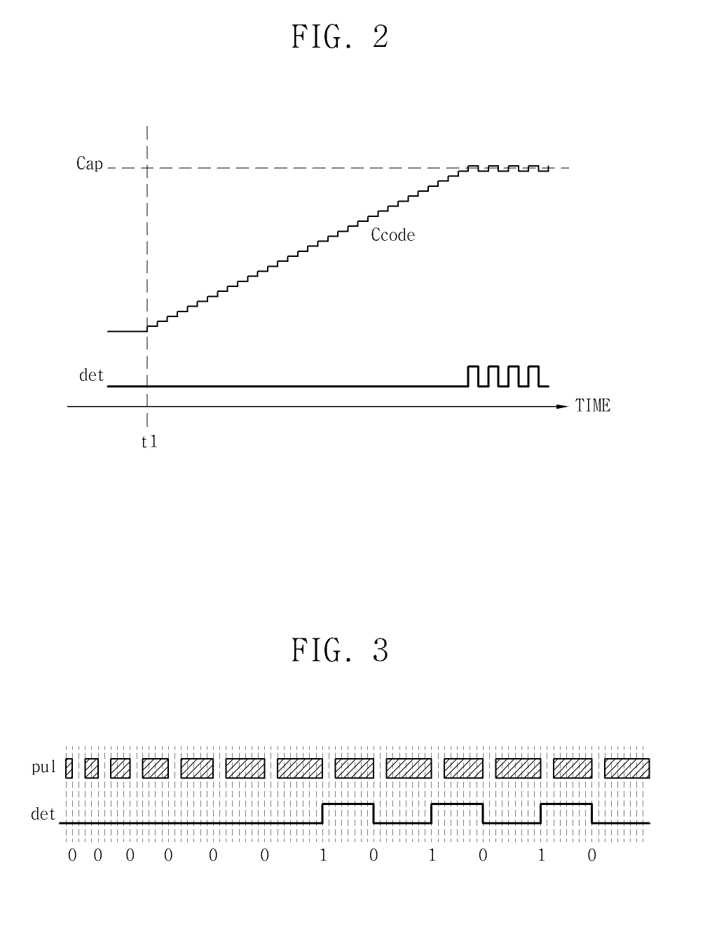

In FIG. 6, a control code Ccode1 indicates changes in a control code output from the control unit 140 when there is no noise, and a control code Ccode2 indicates changes in a control code output from the control unit 140 when noise is irregularly introduced. Also, a control code Ccode3 is shown to compare a control code of FIG. 2 output from the conventional capacitance measurement circuit 1 with the control codes Ccode1 and Ccode2. As illustrated in FIG. 5, in the capacitance measurement circuit 100 according to an exemplary embodiment of the present invention, the pulse signal generation unit 110 outputs the pulse signal pul having the same width four times in response to the control codes Ccode1 and Ccode2 output from the control unit 140. Thus, even if it is the normal state of no noise, a time t3 from a first time t1 when the capacitance measurement circuit 100 starts capacitance measurement until the control code Ccode1 corresponding to a capacitance is output is four times a time t2 until the conventional capacitance measurement circuit 1 outputs the control code Ccode3 corresponding to an applied capacitance. In other words, the capacitance measurement circuit 100 of FIG. 4 needs a longer time than the capacitance measurement circuit 1 of FIG. 1 to measure a capacitance. Also, when noises n1 to n5 are applied, the control unit 140 outputs the same control code Ccode2 again as described above, and thus it will take more than four times the time t2 to measure a capacitance. As shown in the control code Ccode2, when very few noises n1 and n4 are introduced, the noises n1 and n4 have no influence on the level of the sensing signal det, and thus the control unit 140 receiving the sensing signals det of the same level changes the control code Ccode2. However, when the noises n2, n3 and n5 with a level capable of changing the level of the sensing signal det are introduced, the control unit 140 outputs the control code Ccode2 of the same level again, and thus a time to measure a capacitance value increases. On the other hand, in the conventional capacitance measurement circuit 1, the control code Ccode2 varies when the noises n2, n3 and n5 with the level capable of changing the level of the sensing signal det are introduced, and thus a time to measure a capacitance value increases. Thus, in a noise environment, the capacitance measurement circuit 100 may need more than four times a time for the capacitance measurement circuit 1 of FIG. 1 to measure a capacitance value.

The capacitance measurement circuit 100 of FIG. 4 has a disadvantage of a longer measurement time. However, the control codes Ccode1 and Ccode2 corresponding to measured capacitances are hardly affected by noise, and thus the capacitance value CV is output as a very stable value. In other words, the stable and accurate capacitance value CV can be measured without a filter (the capacitance value CV may be the same as a control code output from the control unit 140 or a value corresponding to the control code).

The above-described method of generating pulse signals pul having the same width and outputting the same control code Ccode a plurality of times to measure a capacitance applied through the pad PAD using the pulse signals pul may be referred to as an equal pulse width code (EPW) scheme.

It has been described above that the code generator 141 includes a counter, but the counter may be separately prepared outside the code generator 141. Also, the number of times that the control unit 140 outputs the same control code Ccode may be variously set by a user.

It has been described above that the control code Ccode is changed only when all the sensing signals det have the same value with respect to the same control code Ccode output a plurality of times, but the number of times that the sensing signals det have the same value may be designated as a condition for changing the control code Ccode. For example, when the sensing signal det having the same value is applied to the control unit 140 three times or more in the capacitance measurement circuit 100 in which the same control code Ccode is output four times as described above, the control unit 140 may determine that little noise has been introduced into one of the applied sensing signals det, ignore the sensing signal det, and change the control code Ccode. As additional conditions for changing the control code Ccode, the number of times that the sensing signal det having a value of 0 is applied and the number of times that the sensing signal det having a value of 1 is applied may be separately set. Also, the same method can be used in a case in which the control code Ccode gradually decreases as well as the case illustrated in FIGS. 5 and 6 in which the control code Ccode gradually increases.

FIG. 7 is a flowchart illustrating a capacitance measurement method of the capacitance measurement circuit of FIG. 4.

Referring to FIGS. 4 to 7, the capacitance measurement circuit 100 starts a capacitance measurement operation (S111). In the initial stage of the operation, the capacitance measurement circuit 100 initializes the control code Ccode (S112). An initial value of the control code Ccode may be variously set according to an environment, and may be set to, for example, 0.

After the control code Ccode is initialized, the control unit 140 initializes a number of times n (n is an integer equal to or greater than 0) that the same control code Ccode is generated (S113). The pulse signal generation unit 110 outputs the pulse signal pul having a predetermined width in response to the control code Ccode (S114). The pulse signal detection unit 130 outputs the sensing signal det in response to the delay pulse signal dpul that is delayed and applied through the pulse signal transfer unit 120. The control unit 140 determines whether the sensing signal det has a value of 1 or 0 and stores the value (S115).

Subsequently, the control unit 140 determines whether the number of times n that the same control code Ccode is generated is smaller than a set maximum number of generation times Max_n (Max_n is a natural number) (S116). When the number of times n that the same control code Ccode is generated is smaller than the maximum number of generation times Max_n, the number of times n that the same control code Ccode is generated is increased by one (S 117). Then, a pulse signal corresponding to the same control code Ccode is generated (S114). On the other hand, when the number of times n that the same control code Ccode is generated is not smaller than the maximum number of generation times Max_n, the control unit 140 counts the number of 0s and the number of 1s from the determined sensing signals det (S118).

The control unit 140 determines whether the number of the sensing signals det having a value of 1 with respect to the same control code Ccode is p (p is a natural number equal to or smaller than Max_n) or more, or whether the number of the sensing signals det having a value of 0 is q (q is a natural number equal to or smaller than Max_n) or more (S150). Here, p is a value designated to set the number of times that the sensing signal det having a value of 1 for changing the control code Ccode is applied, and q is a value designated to set the number of times that the sensing signal det having a value of 0 for changing the control code Ccode is applied.

When the number of the sensing signals det having a value of 1 with respect to the same control code Ccode is p or more, the control unit 140 determines that the control code Ccode is greater than a value corresponding to a capacitance applied through the pad PAD, and reduces and outputs the control code Ccode. On the other hand, when the number of the sensing signals det having a value of 0 with respect to the same control code Ccode is q or more, the control unit 140 determines that the control code Ccode has not reached a value corresponding to the capacitance applied through the pad PAD, and increases and outputs the control code Ccode (S 160).

However, when the number of the sensing signals det having a value of 1 is not greater than p and the number of the sensing signals det having a value of 0 is not greater than q, the control unit 140 determines that noise has been present and initializes the number of times n that the control code Ccode is generated without changing the control code Ccode so that the pulse signal pul having the same width is generated again (S113).

Also, the control unit 140 determines whether the control code Ccode is repeated (S170). In other words, the control unit 140 may determine whether or not the control code Ccode having a predetermined value (e.g., k) and the control code Ccode having another predetermined value (e.g., k+1) are alternately and repeatedly generated. In the exemplary embodiment of FIG. 7, the control code Ccode is generated to have the same value Max_n times. As a result, in step 170, the control unit 140 may determine whether or not an operation of generating the control code Ccode having a predetermined value (e.g., k) Max_n times and the control code Ccode having another predetermined value (e.g., k+1) Max_n times is repeated.

When it is determined in step 170 that the control code Ccode is repeated, the control unit 140 determines that the control code Ccode has a value corresponding to the value of the capacitance applied through the pad PAD, and outputs the control code Ccode as the capacitance value CV (S180). (For example, when the control code Ccode having a value of k and the control code Ccode having a value of k+1 are alternately and repeatedly generated as described above, the control unit 140 may output k, k+1, or a value based on k and k+1 as the capacitance value CV.) However, when the control code Ccode is not repeated, the control unit 140 determines that the control code Ccode has not reached the value corresponding to the value of the capacitance applied through the pad PAD, and initializes the number of times n that the control code Ccode is generated so that the pulse signal pul is generated in response to the increased or reduced control code Ccode (S113).

In FIG. 7, p and q may be set to be the same as the maximum number of times Max_n that the same control code Ccode is output. In this case, as illustrated in FIGS. 5 and 6, the control code Ccode is adjusted only when all the sensing signals det have a value of 1 or 0 with respect to the same control codes Ccode.

Although FIG. 7 illustrates a case in which the control unit 140 determines whether or not the control code Ccode is repeated and outputs the control code Ccode as a capacitance value, the control unit 140 may determine whether or not 0 and 1 are repeatedly output and output the control code Ccode as a capacitance value.

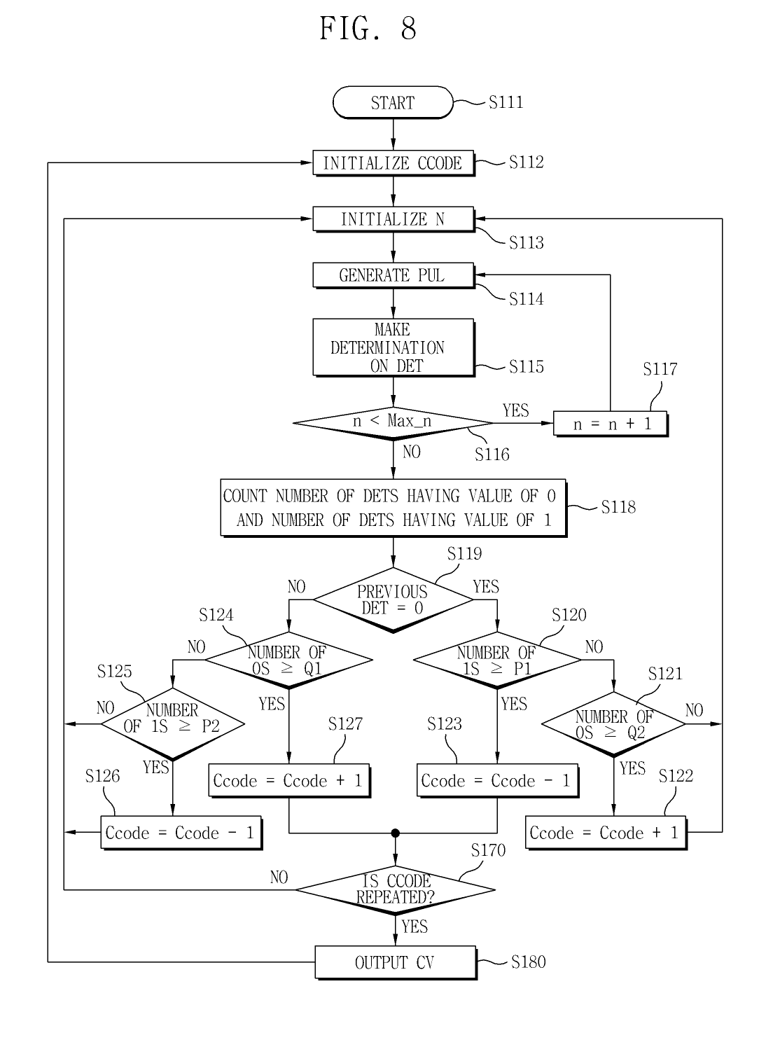

FIG. 8 is a flowchart illustrating a detailed exemplary embodiment of step 150 and step 160 in the flowchart of FIG. 7.

In FIG. 8, step 111 to step 118, step 170, and step 180 are the same as described in FIG. 7 and thus will be understood with reference to the description of FIG. 7. However, in step 112, the sensing signal det as well as the control code Ccode may be initialized.

In step 118, after counting the number of 0s and the number of is from the determined sensing signals det, the control unit 140 determines whether or not the previous sensing signal det was 0 (S119). In this exemplary embodiment, the control unit 140 repeatedly generates the same control code Ccode Max_n times. Not only when the number of the sensing signals det having a value of 0 with respect to the same control code Ccode generated Max_n times is a predetermined value or more but also when all the sensing signals det are 0 with respect to the same control code Ccode generated Max_n times, the control unit 140 may determine that the previous sensing signal det is 0. Also, when the number of the sensing signals det having a value of 1 with respect to the same control code Ccode generated Max_n times is a predetermined value or more, the control unit 140 may determine that the previous sensing signal det is 1.

When the previous sensing signal det is 0, the control unit 140 determines whether or not the number of the sensing signals det having a value of 1 is p1 (p1 is a natural number equal to or smaller than Max_n) or more (S120).

When it is determined in step 120 that the number of the sensing signals det having a value of 1 is smaller than p1, it is determined whether or not the number of the sensing signals det having a value of 0 is q2 (q2 is a natural number equal to or smaller than Max_n) or more (S121).

When it is determined in step 121 that the number of the sensing signals det having a value of 0 is q2 or more, the control unit 140 increases the control code Ccode (S122), and initializes n (S113).

When it is determined in step 121 that the number of the sensing signals det having a value of 0 is smaller than q2, the control unit 140 determines that noise has been present and initializes n without changing the control code Ccode (S113).

When it is determined in step 120 that the number of the sensing signals det having a value of 1 is p1 or more, the control unit 140 reduces the control code Ccode (S123), and determines whether or not the control code Ccode is repeated (S170). In this case, the sensing signal det is changed from 0 to 1.

When it is determined in step 119 that the previous sensing signal det is not 0, that is, the previous sensing signal det is 1, the control unit 140 determines whether or not the number of the sensing signals det having a value of 0 is q1 (q1 is a natural number equal to or smaller than Max_n) or more (S124).

When it is determined in step 124 that the number of the sensing signals det having a value of 0 is smaller than q1, the control unit 140 determines whether or not the number of the sensing signals det having a value of 1 is p2 (p2 is a natural number equal to or smaller than Max_n) or more (S125).

When it is determined in step 125 that the number of the sensing signals det having a value of 1 is p2 or more, the control unit 140 reduces the control code Ccode (S126), and initializes n (S113).

When it is determined in step 125 that the number of the sensing signals det having a value of 1 is smaller than p2, the control unit 140 determines that noise has been present and initializes n without changing the control code Ccode (S113).

When it is determined in step 124 that the number of the sensing signals det having a value of 0 is q1 or more, the control unit 140 increases the control code Ccode (S127), and determines whether or not the control code Ccode is repeated (S 170).

In FIG. 8, p1 and p2 are values having the same characteristic as p described in FIG. 7, and p1 and p2 may be the same value or different values. Also, q1 and q2 are values having the same characteristic as q described in FIG. 7, and q1 and q2 may be the same value or different values.

Some steps illustrated in FIG. 8 may be omitted.

As an example, when the control code Ccode is initialized to the minimum value (e.g., 0) and the sensing signal det is initialized to 0 in step 112, step 119, step 123, step 124 to step 127, and step 170 may be omitted from FIG. 8. In this case, the control unit 140 counts the number of 0s and the number of 1s from the determined sensing signals det in step 118, and then determines whether or not the number of the sensing signals det having a value of 1 is p1 or more (S120). When it is determined in step 120 that the number of the sensing signals det having a value of 1 is p1 or more, the control unit 140 may output the corresponding control code Ccode as the capacitance value CV (S180). When it is determined in step 120 that the number of the sensing signals det having a value of 1 is smaller than p1, the control unit 140 determines whether or not the number of the sensing signals det having a value of 0 is q2 or more (S121). When it is determined in step 121 that the number of the sensing signals det having a value of 0 is q2 or more, the control unit 140 increases the control code Ccode (S122) and then initializes n (S113), and when it is determined in step 121 that the number of the sensing signals det having a value of 0 is smaller than q2, the control unit 140 initializes n without changing the control code Ccode (S113).

As another example, when the control code Ccode is initialized to the largest value and the sensing signal det is initialized to 1 in step 112, step 119, step 120 to step 123, step 127, and step 170 may be omitted from FIG. 8. In this case, the control unit 140 counts the number of 0s and the number of is from the determined sensing signals det in step 118, and then determines whether or not the number of the sensing signals det having a value of 0 is q1 or more (S124). When it is determined in step 124 that the number of the sensing signals det having a value of 0 is q1 or more, the control unit 140 outputs the corresponding control code Ccode as the capacitance value CV (S180). When it is determined in step 124 that the number of the sensing signals det having a value of 0 is smaller than q1, the control unit 140 determines whether or not the number of the sensing signals det having a value of 1 is p2 or more (S125). When it is determined in step 125 that the number of the sensing signals det having a value of 1 is p2 or more, the control unit 140 reduces the control code Ccode (S126) and then initializes n (S113), and when it is determined in step 125 that the number of the sensing signals det having a value of 1 is smaller than p2, the control unit 140 initializes n without changing the control code Ccode (S113).

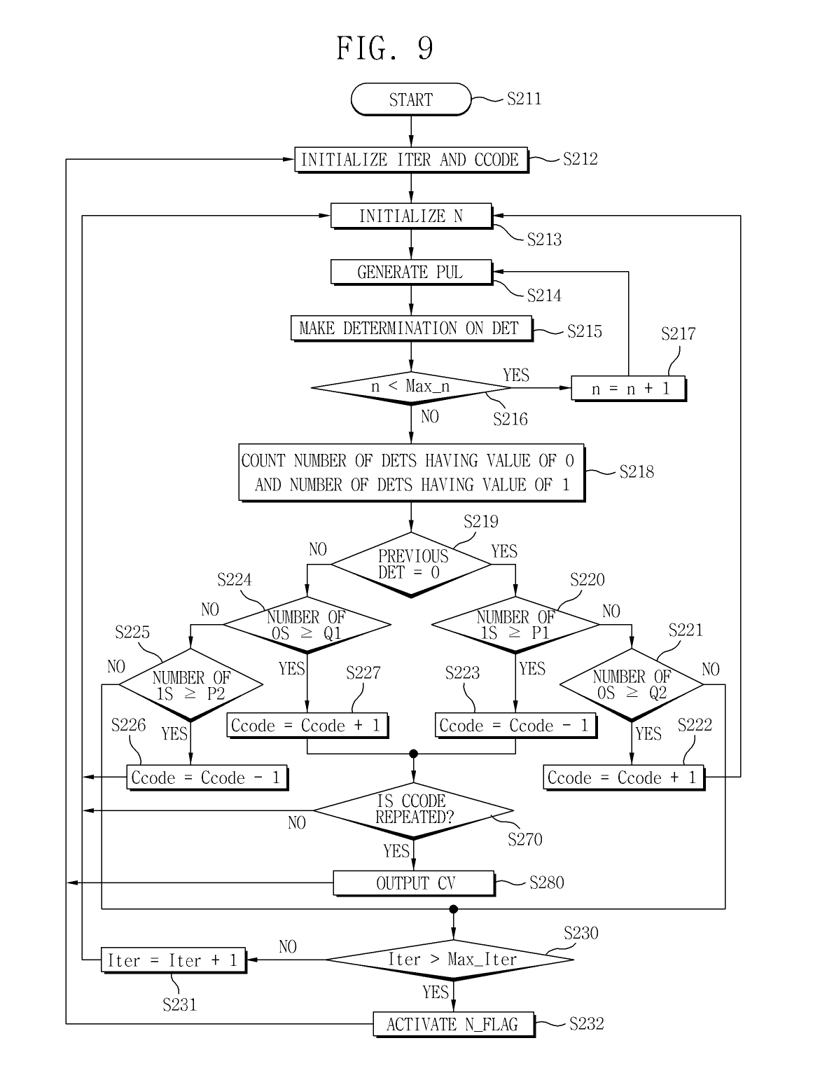

FIG. 9 is a flowchart allowing the capacitance measurement circuit of FIG. 4 to output a noise flag signal.

The capacitance measurement circuit 100 employing the EPW scheme outputs the same control code Ccode Max_n times (e.g., four times) in succession, and changes the control code Ccode when the sensing signals det having the same value are applied with respect to the same control codes Ccode. On the other hand, it has been described that, when the sensing signals det having the same value are not applied, it is determined that noise is present and the same control code Ccode is output Max_n times (e.g., four times) again. However, in an environment with much noise, the sensing signals det having the same value may not be applied in succession. In this case, the control code Ccode may not reach a level corresponding to a capacitance applied to the capacitance measurement circuit 100, and a measurement time may continuously increase. For this reason, in FIG. 9, the capacitance measurement circuit 100 shows a noise flag indicating a noise state and enables initialization or stop of the capacitance measurement operation in a state of much noise.

The capacitance measurement circuit 100 starts a capacitance measurement operation (S211). In the initial stage of the operation, the capacitance measurement circuit 100 first initializes an iteration signal Iter (Iter is an integer equal to or greater than 0) indicating the number of iteration times and the control code Ccode (S212). In step 212, the sensing signal det may also be initialized to a specific value.

Step 213 to step 227, step 270, and step 280 are the same as step 113 to step 127, step 170, and step 180 described in FIGS. 7 and 8, and thus will not be described again.

When it is determined in step 225 that the number of the sensing signals det having a value of 1 is smaller than p2, or it is determined in step 221 that the number of the sensing signals det having a value of 0 is smaller than q2, the control unit 140 determines whether the iteration signal Iter is greater than a set maximum number of iteration times Max_Iter (S230). When the iteration signal Iter is greater than the set maximum number of iteration times Max_Iter, the control code Ccode output with the same value four times has been output as many times as the set maximum number of iteration times Max_Iter and does not have a value corresponding to the applied capacitance. Thus, a noise flag N_flag indicating failure of capacitance measurement is activated and output (S232), and initialization is performed in step 212. On the other hand, when the iteration signal Iter is not greater than the set maximum number of iteration times Max_Iter, the iteration signal Iter is increased by one (S231), and the number of times n that the control code Ccode is generated is initialized to generate the pulse signals pul having the same width again (S213).

Thus, when it is difficult to measure an applied capacitance due to continuously introduced noise, a capacitance measurement circuit employing the method illustrated in FIG. 9 can inform the outside of the noise state by activating the noise flag N_flag and initialize the capacitance measurement operation. Although FIG. 9 illustrates a case of activating the noise flag N_flag (S232) and then initializing the capacitance measurement operation, the capacitance measurement circuit 100 according to an exemplary embodiment of the present invention may stop the capacitance measurement operation after the noise flag N_flag is activated. In this case, the capacitance measurement circuit 100 according to an exemplary embodiment of the present invention may stand by until a user performs manipulation.

For convenience, FIGS. 7 to 9 illustrate a case in which the width of a pulse signal increases from the minimum as an example, but the concept of the present invention can also be applied to a case in which the width of a pulse signal decreases from the maximum.

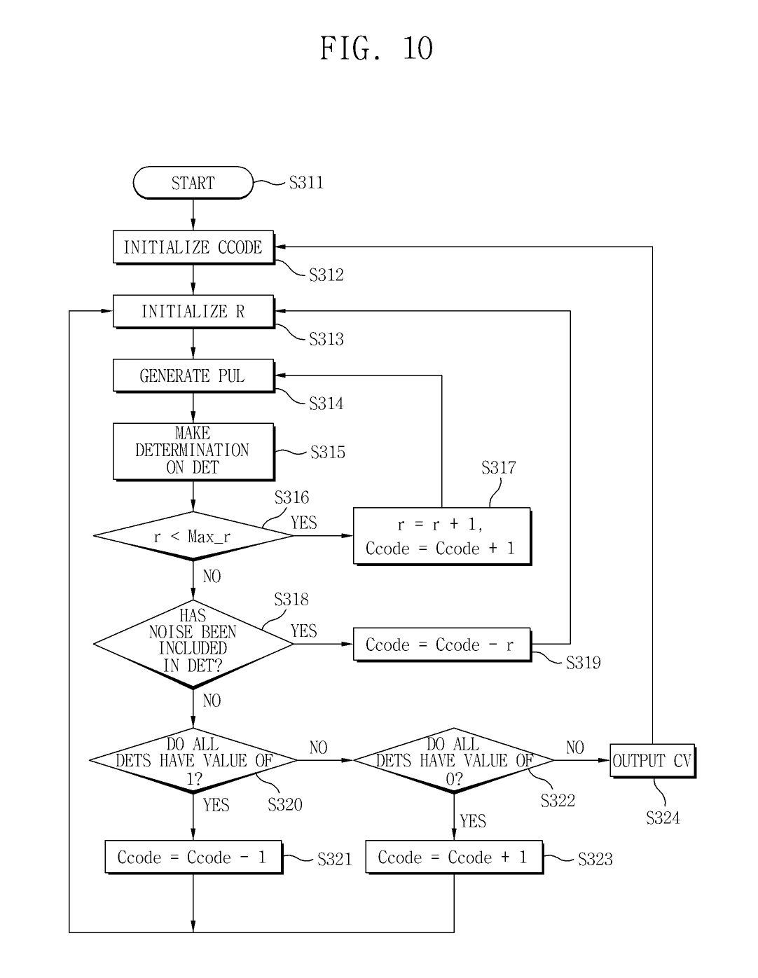

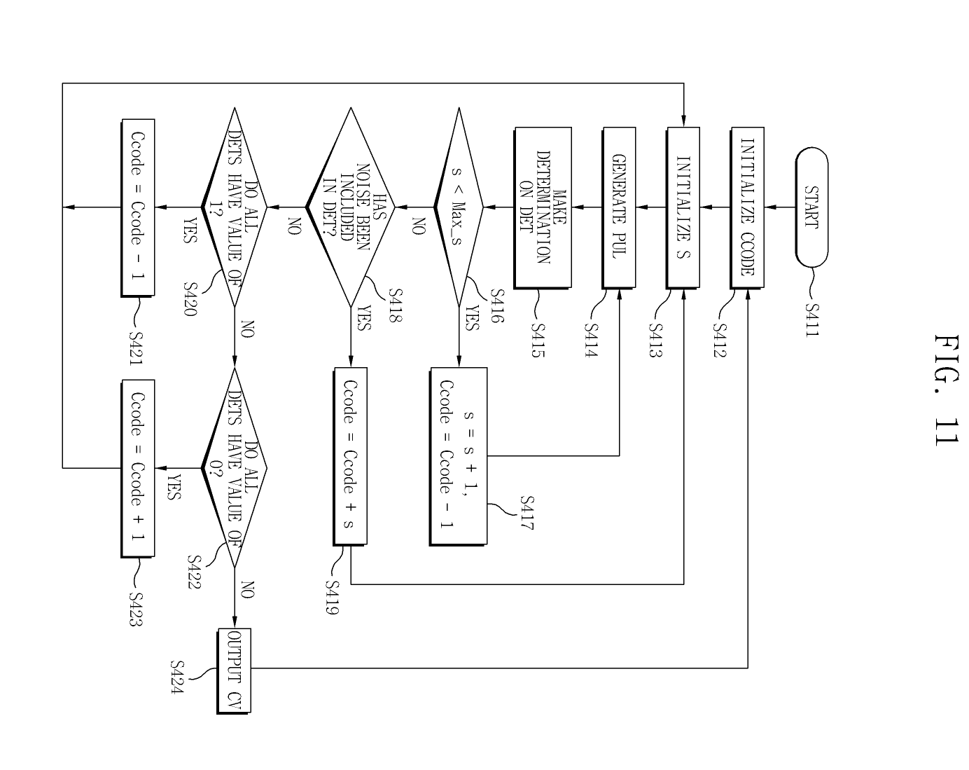

FIG. 10 is a flowchart illustrating another example of a capacitance measurement method of the capacitance measurement circuit of FIG. 4.

The capacitance measurement circuit 100 employing the EPW scheme outputs the same control code a plurality of times in succession and makes a determination on the sensing signals det, thereby changing the control code Ccode. Thus, in comparison with the conventional capacitance measurement circuit 1 illustrated in FIG. 1, the capacitance measurement circuit 100 can stably measure a capacitance but shows a slow measurement speed. For this reason, in FIG. 10, the continuously increasing control code Ccodes are applied, and it is determined whether values of the sensing signals det output to correspond to the respective control codes Ccode are in accordance with a predetermined rule, so that it can be determined whether or not noise is included. Since the continuously increasing control codes Ccode are applied, this method may be referred to as an increasing pulse width code (IPW) scheme to be distinguished from the EPW scheme.

The IPW scheme will be described with reference to FIG. 2. Even when the control codes Ccode sequentially increase in a state of no noise, all the sensing signals det are output with a value of 0. The sensing signals det will not be output with a value of 1 until the control code Ccode has a value corresponding to an applied capacitance. Also, when the control code Ccode has a value greater than the value corresponding to the applied capacitance, the sensing signal det will be output with a value of 1. Thus, if the IPW scheme in which the control unit 140 outputs the continuously increasing control code Ccode regardless of the value of the sensing signal det is used similar to the EPW scheme, it may be determined that noise is included when the sensing signal det successively applied with respect to the continuously increasing control code Ccode is determined to have a value of 1 and then a value of 0.

For example, assuming that the control unit 140 outputs the three continuously increasing control codes Ccode and makes a determination on the sensing signals det corresponding to the respective control codes Ccode, the sensing signals det applied to the control unit 140 in the normal state of no noise may be “111,” “011,” “001,” and “000.” However, if the sensing signals det are applied with “010,” “100,” “101,” and “110,” the sensing signals det are applied with a value of 0 after a value of 1, and thus it may be determined that noise is included. When noise is included, the three continuously increasing control codes Ccode the same as before are output again for measurement, like in the EPW scheme.

The IPW scheme will be described with reference to FIG. 10. The capacitance measurement circuit 100 starts a capacitance measurement operation (S311). In the initial stage of the operation, the capacitance measurement circuit 100 initializes the control code Ccode (S312). After this, the control unit 140 initializes the number of times r (r is an integer equal to or greater than 0) that the continuously increasing control code Ccode is generated (S313). In response to the control code Ccode, the pulse signal generation unit 110 generates and outputs the pulse signal pul having a predetermined width (S314). The pulse signal detection unit 130 outputs the sensing signal det in response to the delay pulse signal dpul that is delayed and applied through the pulse signal transfer unit 120. The control unit 140 determines whether the sensing signal det has a value of 1 or 0 and stores the value (S315).

Subsequently, it is determined whether the number of times r that the continuously increasing control code Ccode is generated is smaller than a set maximum number of generation times Max_r (Max_r is a natural number) (S316). When the number of times r that the control code Ccode is generated is smaller than the maximum number of generation times Max_r, the number of times r that the continuously increasing control code Ccode is generated and the control code Ccode are each increased by one (S317). Then, a pulse signal corresponding to the increased control code Ccode is generated (S314). However, when the number of times r that the continuously increasing control code Ccode is generated is not smaller than the maximum number of generation times Max_r, the control unit 140 determines whether or not noise is included according to the above mentioned rule (S318). When it is determined that noise is included, it needs to take a measurement relating to the continuously increasing control code Ccode again. Thus, the number of times r that the continuously increasing control code Ccode is generated is subtracted from the increased control code Ccode (S319), and the number of times r that the continuously increasing control code Ccode is generated is initialized again (S313). When the number of times r that the continuously increasing control code Ccode is generated is subtracted from the increased control code Ccode, the number of times r that the control code Ccode is generated has the same value as the maximum number of generation times Max_r, and thus the same result is also obtained subtracting the maximum number of generation times Max_r from the increased control code Ccode.

Meanwhile, when it is determined that noise is not included, the control unit 140 determines whether all the sensing signals det have a value of 1 (S320). According to the noise determination rules, if a sensing signal has a value of 1 and then a value of 0, it may be determined that noise is included. However, when the sensing signal det needs to be output with values of “011,” “001,” and “000” but is output with “111” due to noise, it cannot be accurately determined whether or not noise is included according to the noise determination rules. Thus, the control code Ccode is reduced by one (S321), and the number of times r that the continuously increasing control code Ccode is generated is initialized again (S313).

When all the sensing signals det do not have a value of 1, the control unit 140 determines whether all the sensing signals det have a value of 0 (S322). This is to accurately determine whether or not noise is included, like a determination of whether or not all the sensing signals det have a value of 1. Thus, the control code Ccode is increased by one (S323), and the number of times r that the continuously increasing control code Ccode is generated is initialized again (S313).

Meanwhile, if all the sensing signals det have a value of 1 or none of the sensing signals det has a value of 0, noise has not been included, and the control code Ccode obtained when the sensing signal det outputs 1 for the first time may be determined as the control code Ccode having a value corresponding to an applied capacitance. Thus, the corresponding control code Ccode may be output as the capacitance value CV (S324). Thus far, the control code Ccode is increased and reduced by, for convenience, one in step 321 and step 323, but may be increased and reduced by r or another value.

A capacitance measurement circuit employing the IPW scheme can output the capacitance value CV faster than a capacitance measurement circuit employing the EPW scheme.

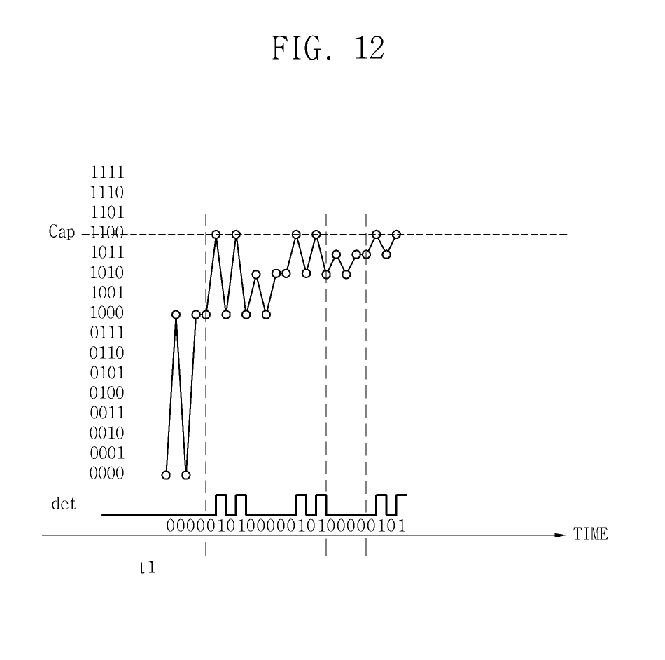

FIG. 11 is a flowchart illustrating still another example of a capacitance measurement method of the capacitance measurement circuit of FIG. 4.

FIG. 11 illustrates a decreasing pulse width code (DPW) scheme of outputting a continuously decreasing control code Ccode, unlike the IPW scheme of FIG. 10. In the capacitance measurement circuit employing the DPW scheme, when the control unit 140 outputs the three continuously increasing control codes Ccode and makes a determination on the sensing signals det corresponding to the respective control codes Ccode, the sensing signals det applied to the control unit 140 in the normal state of no noise may be “111,” “100,” “110,” and “000.” However, when the sensing signals det are applied with “010,” “011,” “101,” and “001,” the sensing signals det are applied with a value of 1 after a value of 0, and thus it may be determined that noise is included.

In FIG. 11, when a number of times s (s is an integer equal to or greater than 0) that the continuously decreasing control code Ccode is generated is smaller than a maximum number of generation times Max_s (Max_s is a natural number) (S416), the number of times s that the control code Ccode is generated is increased by one, and the control code Ccode is reduced by one (S417). When it is determined that noise is included in the sensing signal det (S418), the number of times s that the control code Ccode is generated is added to the control code Ccode (S419) because the control code Ccode is continuously reduced. In the DPW scheme, unlike the IPW scheme, the control code Ccode obtained when the sensing signal det outputs 0 for the first time may be determined as the control code Ccode having a value corresponding to an applied capacitance, and the corresponding control code Ccode may be output as the capacitance value CV (S424).

The remaining constitution is the same as FIG. 10 and will not be described again.

Although not shown in the drawing, the maximum number of iteration times Max_Iter may also be designated to activate a noise flag in the IPW scheme and the DPW scheme as illustrated in FIG. 9.

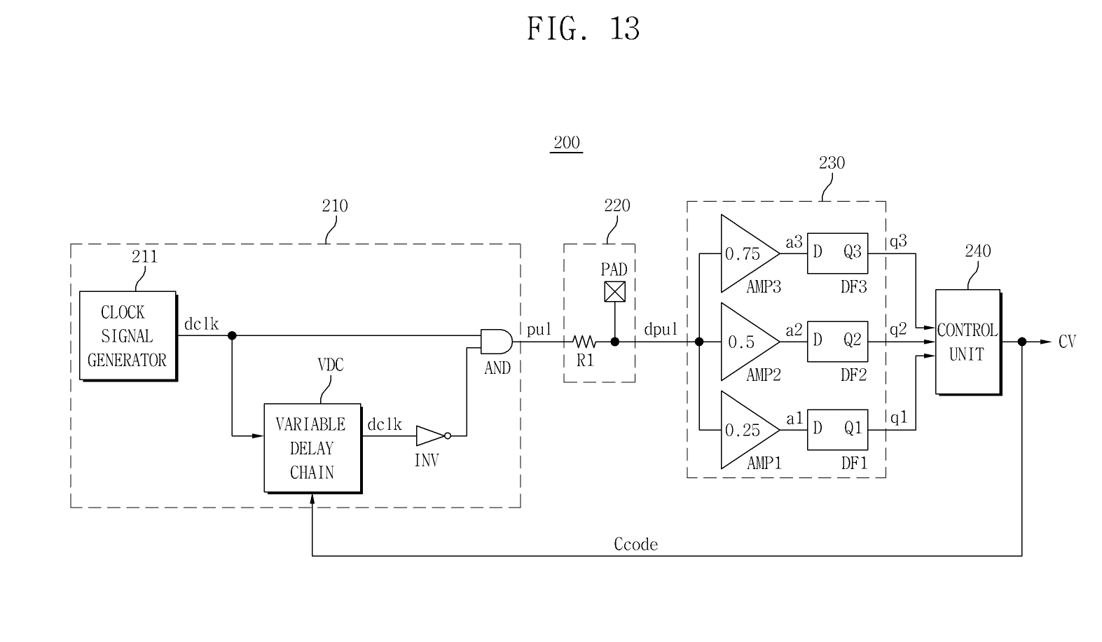

FIG. 12 illustrates a concept of another example of a capacitance measurement method of a capacitance measurement circuit according to an exemplary embodiment of the present invention.

The capacitance measurement method illustrated in FIG. 12 is a method of repeatedly applying control codes corresponding to the maximum and minimum of a specific range to check whether or not a capacitance applied through a pad PAD is within the range, and may be referred to as an alternative pulse width code (APW) scheme.

FIG. 12 illustrates a case in which a capacitance measurement circuit 100 can output a 4-bit capacitance value CV as an example of the APW scheme. In the capacitance measurement circuit 100 outputting the 4-bit capacitance value CV, a control unit 140 generates and repeatedly outputs “0000” and “1000,” which are the control codes Ccode corresponding to the lower half of a range, a predetermined number of times. Here, the control codes Ccode of “0000” and “1000” are repeatedly output to determine whether or not noise is included in a similar way to the EPW scheme. FIG. 12 illustrates the example in which control codes corresponding to the minimum and maximum of a specific range are applied two times. When a capacitance applied through the pad PAD is greater than the range corresponding to the applied control code Ccode, the sensing signal det will be output with “0000” with respect to the repeated control code Ccode. Also, when the capacitance is smaller than the range corresponding to the applied control code Ccode, the sensing signal det will be output with “1111” with respect to the repeated control code Ccode. Further, when the capacitance is included in the range corresponding to the applied control code Ccode, the sensing signal det will be output with “0101” with respect to the repeated control code Ccode. Thus, when the sensing signal det is output with a value other than “0000,” “0101,” or “1111,” it may be determined that noise is included.

When the sensing signal det is “0000” or “1111,” the control unit 140 determines that the applied capacitance does not correspond to the range of the control code Ccode, and generates and outputs the control code Ccode corresponding to the remaining range. At this time, the control unit 140 may generate and output the control code Ccode corresponding to half of the remaining range. Meanwhile, when the sensing signal is “0101,” the control unit 140 determines that the applied capacitance corresponds to the range of the control code Ccode. To measure the accurate capacitance, the control code Ccode corresponding to half the range of the corresponding control code Ccode may be generated and output. In other words, the capacitance value CV may be measured by gradually reducing the range of the control code Ccode until the capacitance value CV corresponding to the applied capacitance can be output.

The above method has been well known as a divide and conquer algorithm. However, the APW scheme of the present invention is not limited to the divide and conquer algorithm, and may be applied to all methods in which the control unit 140 repeatedly outputs the control code Ccode with a value corresponding to a specific range and determines whether or not an applied capacitance is included in the range.

The flowchart of a method of measuring the capacitance value CV using the APW scheme is similar to those of the IPW scheme illustrated in FIG. 10 and the DPW scheme illustrated in FIG. 11, and thus will not be illustrated again. Also, a maximum number of iteration times Max_Iter may be designated to activate a noise flag.

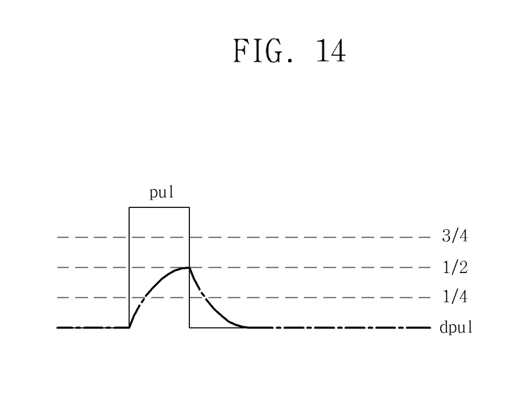

FIG. 13 is a block diagram of a capacitance measurement circuit according to another exemplary embodiment of the present invention, and FIG. 14 is a diagram illustrating a process for a pulse signal detection unit of FIG. 13 to detect a delay pulse signal.

Like the capacitance measurement circuit 100 of FIG. 4, a capacitance measurement circuit 200 of FIG. 13 includes a pulse signal generation unit 210, a pulse signal transfer unit 220, a pulse signal detection unit 230, and a control unit 240. However, in the capacitance measurement circuit 200 shown in FIG. 13, the pulse signal detection unit 230 has a different constitution than the pulse signal detection unit 130 of the capacitance measurement circuit 100 of FIG. 4.

In FIG. 13, the pulse signal detection unit 230 may include a plurality of amplifiers AMP1 to AMP3 and a plurality of flip-flops DF1 to DF3. The flip-flops DF1 to DF3 may be D-flip-flops or other flip-flops. The respective amplifiers AMP1 to AMP3 have different gains. In other words, the respective amplifiers AMP1 to AMP3 amplify a delay pulse signal dpul transferred from the pulse signal transfer unit 220 with different gains and output amplification signals a1 to a3 to the corresponding flip-flops DF1 to DF3. In FIG. 13, the first amplifier AMP1 amplifies the delay pulse signal dpul to output the first amplification signal also that 1/4 level of the delay pulse signal dpul can be sensed, the second amplifier AMP2 amplifies the delay pulse signal dpul to output the second amplification signal a2 so that 2/4 level of the delay pulse signal dpul can be sensed, and the third amplifier AMP3 amplifies the delay pulse signal dpul to output the third amplification signal a3 so that 3/4 level of the delay pulse signal dpul can be sensed. The respective flip-flops DF1 to DF3 latch the amplification signals a1 to a3 output from the corresponding amplifiers and output latch signals q1 to q3. Here, the latch signals q1 to q3 correspond to the sensing signal det of FIG. 4. However, since the amplification signals a1 to a3 are latched and then output as the latch signals q1 to q3, the latch signals q1 to q3 sense the level of the delay pulse signal dpul transferred from the pulse signal transfer unit 220. While the sensing signal det is obtained by sensing the delay pulse signal dpul as it is, the latch signals q1 to q3 are obtained by amplifying and latching the delay pulse signal dpul and thus may indicate the level of the delay pulse signal dpul. Assuming that the sensing signal det generally senses 1/2 level of the delay pulse signal dpul and is output, the second latch signal q2 may be determined as a signal corresponding to the sensing signal det.

When a touch object comes in contact with a pad PAD and a capacitance is applied to the pulse signal transfer unit 220, a pulse signal pul applied from the pulse signal generation unit 210 is delayed by the capacitance of the touch object and a resistor R1 in the pulse signal transfer unit 220 and output as the delay pulse signal dpul having a gradually increasing shape as shown in FIG. 14. Here, a time constant of the delay pulse signal dpul is determined by the resistor R1 and the capacitance of the touch object applied through the pad PAD.

In the pulse signal detection unit 230, the first amplifier AMP1 and the first flip-flop DF1 sense 1/4 of the maximum level that the delay pulse signal dpul can have and output the first latch signal q1, the second amplifier AMP2 and the second flip-flop DF2 sense 1/2 of the maximum level that the delay pulse signal dpul can have and output the second latch signal q2, and the third amplifier AMP3 and the third flip-flop DF3 sense 3/4 of the maximum level that the delay pulse signal dpul can have and output the third latch signal q3. Since the delay pulse signal dpul is shown in the form as shown in FIG. 14, the latch signals q1 to q3 applied to the control unit 240 may be changed to 1 in sequence. The first to third latch signals q1 to q3 indicate the level of the delay pulse signal dpul and thus may be referred to as a multi-level code (MLC), and the MLC (q3, q2 and q1) may be expressed by binary codes.

Since the delay pulse signal dpul gradually increases as mentioned above, the MLC (q3, q2 and q1) will be changed to “000,” “001,” “011,” and “111” in sequence when there is no noise. When the MLC is not changed in the sequence, the capacitance measurement circuit 200 may determine that noise is included in the MLC.

When the time constant of the delay pulse signal dpul and the pulse width of the pulse signal pul are as shown in FIG. 14, the MLC (q3, q2 and q1) output by the pulse signal detection unit 230 of FIG. 13 will be changed to “000,” “001,” “011,” and “111” in sequence. The time constant of the delay pulse signal dpul is as shown in FIG. 14, but when the pulse width of the pulse signal pul is smaller than that shown in FIG. 14, the MLC (q3, q2 and q1) output by the pulse signal detection unit 230 of FIG. 13 will be changed to “000,” “001,” “001,” and “001,” or “000,” “000,” “000,” and “000” in sequence.

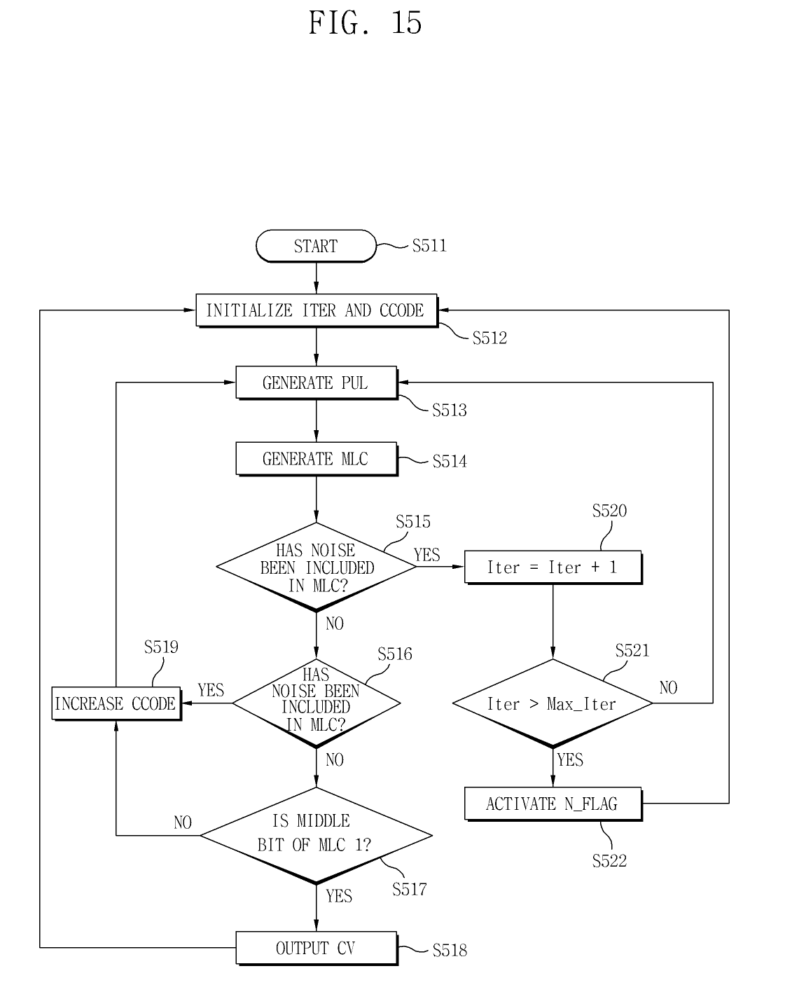

FIG. 15 is a flowchart illustrating a capacitance measurement method of the capacitance measurement circuit of FIG. 13.

The capacitance measurement circuit 200 starts a capacitance measurement operation (S511). In the initial stage of the operation, the capacitance measurement circuit 200 first initializes an iteration signal Iter (Iter is an integer equal to or greater than 0) indicating the number of iteration times and the control code Ccode (S512). At this time, the control code Ccode may be initialized to the minimum (e.g., 0). The pulse signal generation unit 210 outputs the pulse signal pul having a predetermined width in response to the control code Ccode (S513). Subsequently, the pulse signal detection unit 230 senses the level of the delay pulse signal dpul that is delayed and applied through the pulse signal transfer unit 220, thereby generating an MLC (S514).

The control unit 240 checks a change in the generated MLC, thereby determining whether or not noise is included (S515). When noise is not included in the MLC and all bits of the MLC are output with 0, the control unit 240 determines that the control code Ccode has not reached a value corresponding to a capacitance applied through the pad PAD, and increases and outputs the control code Ccode (S519). However, when 1 is included in the MLC, it is determined whether the middle bit is 1 (S517). In other words, it is determined whether the second latch signal q2 is 1. As mentioned above, the second latch signal q2 may be determined as a signal corresponding to the sensing signal det. Thus, when the second latch signal q2 that is the middle bit of the MLC is 1, the control unit 240 determines that the control code Ccode has reached a value corresponding to the capacitance applied through the pad PAD, and outputs the control code Ccode as the capacitance value CV (S518).

Meanwhile, the control unit 240 checks the transition sequence of the MLC, and increases the iteration signal Iter by one when noise is included in the MLC (S520). Subsequently, it is determined whether the increased iteration signal Iter is greater than a set maximum iteration signal Max_Iter (Max_Iter is a natural number) (S521). When the iteration signal Iter is greater than the set maximum iteration signal Max_Iter, a noise flag N_flag indicating failure of capacitance measurement is activated and output (S522). On the other hand when the iteration signal Iter is not greater than the set maximum iteration signal Max_Iter, the pulse signal pul having the same width is generated again (S513). While the EPW, IPW, DPW, and APW schemes generate the control code Ccode a plurality of times to adjust the width of the pulse signal pul and thereby determine whether or not noise is included, an MLC enables check of whether or not noise is included by generating the pulse signal pul only once.

The MLC can be applied to various schemes, such as the EPW, IPW, DPW, and APW schemes, as well as the conventional capacitance measurement method.

The present invention relates to a capacitance measurement circuit and method, and particularly, can be usefully used in an industry relating to a capacitance measurement circuit capable of reducing influence of noise.

While the invention has been shown and described with reference to certain exemplary embodiments thereof, it will be understood by those skilled in the art that various changes in form and details may be made therein without departing from the spirit and scope of the invention as defined by the appended claims.

1. A capacitance measurement circuit, comprising:
a pulse signal generation unit configured to generate a pulse signal having a pulse width corresponding to a control code;
a pulse signal transfer unit having a pad, and configured to delay the pulse signal according to a capacitance applied through the pad and output the delayed pulse signal as a delay pulse signal;
a pulse signal detection unit configured to output a sensing signal by detecting the delay pulse signal; and
a control unit configured to generate the control code a plurality of times according to designated rules, apply the generated control codes to the pulse signal generation unit, and determine whether or not to change the control code by making a determination on the plurality of sensing signals corresponding to the respective generated control codes.

2. The capacitance measurement circuit of claim 1, wherein the control unit generates the control code having the same value n times (n is a natural number), applies the generated control codes to the pulse signal generation unit, and stores values of the sensing signals corresponding to the respective control codes generated n times.

3. The capacitance measurement circuit of claim 2, wherein the control unit increases and outputs the control code when a number of 0 is q or more (q is a natural number equal to or smaller than n) at the stored values of the plurality of sensing signals.

4. The capacitance measurement circuit of claim 2, wherein the control unit reduces and outputs the control code when a number of 1 is p or more (p is a natural number equal to or smaller than n) at the stored values of the plurality of sensing signals.

5. The capacitance measurement circuit of claim 2, wherein the control unit increases and outputs the control code when a number of 0 is q or more (q is a natural number equal to or smaller than n) at the stored values of the plurality of sensing signals,
reduces and outputs the control code when a number of 1 is p or more (p is a natural number equal to or smaller than n) at the stored values of the plurality of sensing signals, and
outputs the control code as a capacitance value when an increase and reduction in the control code are repeated a predetermined number of times or more.

6. The capacitance measurement circuit of claim 2, wherein, when a number of 1 is p or less (p is a natural number equal to or smaller than n) at the stored values of the plurality of sensing signals, or when a number of 0 is q or less (q is a natural number equal to or smaller than n) at the stored values of the plurality of sensing signals, the control unit determines that noise is included, generates the same control code n times again without changing the control code, and applies the generated control codes to the pulse signal generation unit.

7. The capacitance measurement circuit of claim 6, wherein the control unit increases a number of iteration times when the same control code is generated n times again and applied to the pulse signal generation unit, and
activates a noise flag when the number of iteration times is greater than a set maximum number of iteration times.

8. The capacitance measurement circuit of claim 7, wherein, when the number of iteration times is greater than the set maximum number of iteration times, the control unit initializes the control code and the number of iteration times.

9. The capacitance measurement circuit of claim 1, wherein the control unit generates r (r is a natural number) sequentially increasing control codes, applies the r control codes to the pulse signal generation unit, sequentially stores values of the sensing signals corresponding to the respective r control codes, and determines that noise is included to output the r sequentially increasing control codes again when, among the plurality of stored sensing signals, a sensing signal having a value of 0 follows a sensing signal having a value of 1.

10. The capacitance measurement circuit of claim 9, wherein the control unit increases a number of iteration times when the r sequentially increasing control codes are applied to the pulse signal generation unit, and
activates and outputs a noise flag when the number of iteration times is greater than a set maximum number of iteration times.

11. The capacitance measurement circuit of claim 10, wherein, when the number of iteration times is greater than the set maximum number of iteration times, the control unit initializes the control code and the number of iteration times.

12. The capacitance measurement circuit of claim 9, wherein, when all the plurality of stored sensing signals have a value of 1, the control unit reduces and outputs the control code.

13. The capacitance measurement circuit of claim 9, wherein, when all the plurality of stored sensing signals have a value of 0, the control unit increases and outputs the control code.

14. The capacitance measurement circuit of claim 9, wherein the control unit outputs a control code corresponding to a sensing signal having a value of 1 for the first time as a capacitance value when, among the plurality of stored sensing signals, all sensing signals stored after a sensing signal having a value of 0 have a value of 1.

15. The capacitance measurement circuit of claim 1, wherein the control unit generates s (s is a natural number) sequentially decreasing control codes, applies the control codes to the pulse signal generation unit, sequentially stores values of the sensing signals corresponding to the respective s control codes, and determines that noise is included to output the s sequentially decreasing control codes again when, among the plurality of stored sensing signals, a sensing signal having a value of 1 follows a sensing signal having a value of 0.

16. The capacitance measurement circuit of claim 15, wherein the control unit increases a number of iteration times when the s sequentially decreasing control codes are applied to the pulse signal generation unit, and
activates and outputs a noise flag when the number of iteration times is greater than a set maximum number of iteration times.

17. The capacitance measurement circuit of claim 16, wherein, when the number of iteration times is greater than the set maximum number of iteration times, the control unit initializes the control code and the number of iteration times.

18. The capacitance measurement circuit of claim 15, wherein, when all the plurality of stored sensing signals have a value of 1, the control unit reduces and outputs the control code.

19. The capacitance measurement circuit of claim 15, wherein, when all the plurality of stored sensing signals have a value of 0, the control unit increases and outputs the control code.

20. The capacitance measurement circuit of claim 15, wherein the control unit outputs a control code corresponding to a sensing signal having a value of 0 for the first time as a capacitance value when, among the plurality of stored sensing signals, all sensing signals stored after a sensing signal having a value of 1 have a value of 0.

21. The capacitance measurement circuit of claim 1, wherein the control unit alternately generates control codes corresponding to a maximum and minimum of a first range set within a largest value that the control code can have a plurality of times, applies the generated control codes to the pulse signal generation unit, sequentially stores values of the sensing signals corresponding to the respective generated control codes, and determines that noise is included to alternately output the control codes corresponding to the maximum and minimum of the first range a plurality of times again when, among the plurality of stored sensing signals, the sensing signal has a value of 1 with respect to the control code corresponding to the minimum and the sensing signal has a value of 0 with respect to the control code corresponding to the maximum.

22. The capacitance measurement circuit of claim 21, wherein the control unit increases a number of iteration times when the control codes corresponding to the maximum and minimum of the first range are alternately applied to the pulse signal generation unit a plurality of times again, and
activates and outputs a noise flag when the number of iteration times is greater than a set maximum number of iteration times.

23. The capacitance measurement circuit of claim 22, wherein, when the number of iteration times is greater than the set maximum number of iteration times, the control unit initializes the control code and the number of iteration times.

24. The capacitance measurement circuit of claim 21, wherein, when all the plurality of stored sensing signals have a value of 1, the control unit alternately generates control codes corresponding to a maximum and minimum of a range having a lower value than the first range a plurality of times and applies the generated control codes to the pulse signal generation unit.

25. The capacitance measurement circuit of claim 21, wherein, when all the plurality of stored sensing signals have a value of 0, the control unit alternately generates control codes corresponding to a maximum and minimum of a range having a higher value than the first range a plurality of times and applies the generated control codes to the pulse signal generation unit.

26. The capacitance measurement circuit of claim 21, wherein the control unit alternately generates control codes corresponding to a maximum and minimum of a narrower range than the first range within the first range a plurality of times and applies the generated control codes to the pulse signal generation unit when, among the plurality of stored sensing signals, the sensing signal corresponding to the control code corresponding to the minimum has a value of 0 and the sensing signal corresponding to the control code corresponding to the maximum has a value of 1.

27. The capacitance measurement circuit of claim 26, wherein the control unit outputs the control code as a capacitance value when a difference between values of the control codes corresponding to the maximum and minimum is a smallest value.

28. The capacitance measurement circuit of claim 1, wherein the pulse signal generation unit includes:
a clock signal generator configured to generate a clock signal;
a variable delay chain configured to delay the clock signal for a delay time corresponding to the control code and output a delay clock signal;
and a logical operation unit configured to generate the pulse signal having a pulse width corresponding to the delay time in response to the clock signal and the delay clock signal.

29. The capacitance measurement circuit of claim 1, wherein the pulse signal transfer unit further includes a resistor connected between the pulse signal generation unit and the pulse signal detection unit, and configured to disturb transfer of the pulse signal together with the capacitance applied through the pad.

30. The capacitance measurement circuit of claim 28, wherein the pulse signal detection unit includes:
a flip-flop configured to generate an output signal toggled according to the delay pulse signal in response to the clock signal; and
a period determiner configured to determine a period of the output signal of the flip-flop and output the sensing signal.

31. The capacitance measurement circuit of claim 1, wherein the pulse signal detection unit includes:
a plurality of amplifiers configured to amplify the delay pulse signal with different gains respectively and output the amplification signals respectively; and
a plurality of flip-flops corresponding to the respective amplifiers, and configured to latch the amplification signals and output the latch signals, respectively.

32. The capacitance measurement circuit of claim 31, wherein the control unit determines whether or not noise is included by sensing a change in the plurality of latch signals.

33. A capacitance measurement method, comprising:
generating a pulse signal having a pulse width corresponding to a control code;
outputting a delay pulse signal by delaying the pulse signal in response to a capacitance applied through a pad;
outputting a sensing signal by detecting the delay pulse signal; and
generating the control code a plurality of times, applying the generated control codes to a pulse signal generation unit, and determining whether or not to change the control code by making a determination on the plurality of sensing signals corresponding to the respective generated control codes.

34. The capacitance measurement method of claim 33, wherein determining whether or not to change the control code includes:
generating the control code having the same value n (n is a natural number) times and applying the generated control codes to the pulse signal generation unit; and
storing values of the sensing signals corresponding to the respective n control codes.

35. The capacitance measurement method of claim 34, wherein determining whether or not to change the control code further includes increasing and outputting the control code when a number of 0 is q (q is a natural number equal to or smaller than n) or more at the plurality of stored sensing signals.

36. The capacitance measurement method of claim 34, wherein determining whether or not to change the control code further includes reducing and outputting the control code when a number of 1 is p (p is a natural number equal to or smaller than n) or more at the plurality of stored sensing signals.

37. The capacitance measurement method of claim 34, wherein determining whether or not to change the control code further includes:
increasing and outputting the control code when a number of 0 is q (q is a natural number equal to or smaller than n) or more at the plurality of stored sensing signals and reducing and outputting the control code when a number of 1 is p (p is a natural number equal to or smaller than n) or more at the plurality of stored sensing signals; and
outputting the control code as a capacitance value when an increase and reduction in the control code are repeated a predetermined number of times or more.

38. The capacitance measurement method of claim 34, wherein determining whether or not to change the control code further includes, when a number of 1 is p (p is a natural number equal to or smaller than n) or less at the plurality of stored sensing signals, or when a number of 0 is q (q is a natural number equal to or smaller than n) or less at the plurality of stored sensing signals, determining that noise is included, generating the same control code n times again without changing the control code, and applying the generated control codes to the pulse signal generation unit.

39. The capacitance measurement method of claim 33, wherein determining whether or not to change the control code includes:
generating r (r is a natural number) sequentially increasing control codes and applying the r control codes to the pulse signal generation unit;
sequentially storing values of sensing signals corresponding to the respective r control codes; and
determining that noise is included and outputting the r sequentially increasing control codes again when, among the plurality of stored sensing signals, a sensing signal having a value of 0 follows a sensing signal having a value of 1.

40. The capacitance measurement method of claim 39, wherein determining whether or not to change the control code further includes:
reducing and outputting the control code when all the plurality of stored sensing signals have a value of 1; and
increasing and outputting the control code when all the plurality of stored sensing signals have a value of 0.

41. The capacitance measurement method of claim 39, wherein determining whether or not to change the control code further includes outputting a control code corresponding to a sensing signal having a value of 1 for the first time as a capacitance value when, among the plurality of stored sensing signals, all sensing signals stored after a sensing signal having a value of 0 have a value of 1.

42. The capacitance measurement method of claim 33, wherein determining whether or not to change the control code includes:
generating s (s is a natural number) sequentially decreasing control codes and applying the s control codes to the pulse signal generation unit;
sequentially storing values of the sensing signals corresponding to the respective s control codes; and
determining that noise is included to output the s sequentially decreasing control codes again when, among the plurality of stored sensing signals, a sensing signal having a value of 1 follows a sensing signal having a value of 0.

43. The capacitance measurement method of claim 42, wherein determining whether or not to change the control code further includes:
reducing and outputting the control code when all the plurality of stored sensing signals have a value of 1; and
increasing and outputting the control code when all the plurality of stored sensing signals have a value of 0.

44. The capacitance measurement method of claim 42, wherein determining whether or not to change the control code further includes outputting a control code corresponding to a sensing signal having a value of 0 for the first time as a capacitance value when, among the plurality of stored sensing signals, all sensing signals stored after a sensing signal having a value of 1 have a value of 0.

45. The capacitance measurement method of claim 33, wherein determining whether or not to change the control code includes:
alternately generating control codes corresponding to a maximum and minimum of a first range set within a largest value that the control code can have a plurality of times, and applying the generated control codes to the pulse signal generation unit;
sequentially storing values of the sensing signals corresponding to the respective generated control codes; and
determining that noise is included to alternately output the control codes corresponding to the maximum and minimum of the first range a plurality of times again when, among the plurality of stored sensing signals, the sensing signal has a value of 1 with respect to the control code corresponding to the minimum and the sensing signal has a value of 0 with respect to the control code corresponding to the maximum.

46. The capacitance measurement method of claim 45, wherein determining whether or not to change the control code further includes:
when all the plurality of stored sensing signals have a value of 1, alternately generating control codes corresponding to a maximum and minimum of a range having a lower value than the first range a plurality of times, and applying the generated control codes to the pulse signal generation unit;
when all the plurality of stored sensing signals have a value of 0, alternately generating control codes corresponding to a maximum and minimum of a range having a higher value than the first range a plurality of times, and applying the generated control codes to the pulse signal generation unit; and
when, among the plurality of stored sensing signals, the sensing signal corresponding to the control code corresponding to the minimum has a value of 0 and the sensing signal corresponding to the control code corresponding to the maximum has a value of 1, alternately generating control codes corresponding to a maximum and minimum of a narrower range than the first range within the first range a plurality of times, and applying the generated control codes to the pulse signal generation unit.

47. The capacitance measurement method of claim 46, wherein determining whether or not to change the control code further includes outputting the control code as a capacitance value when a difference between values of the control codes corresponding to the maximum and minimum is a smallest value.
